(19) United States
(12) Patent Application Publication
(10) Pub. No.: US 2003/0188889 A1
(43) Pub. Date: Oct. 9, 2003

(54) Printed circuit board and method for producing it

(75) Inventors: Peter Straub, Oberwil (CH); Gregor Muller, Neuheim (CH)

Correspondence Address: TAROLLI, SUNDHEIM, COVELL & TUMMINO L.L.P., 526 SUPERIOR AVENUE, SUITE 1111, CLEVEVLAND, OH, 44114, US

(73) Assignee: PPC Electronic AG

(21) Appl. No.: 10/235,593

(22) Filed: Sep. 4, 2002

(30) Foreign Application Priority Data
Apr. 9, 2002 (CH) CH 0601/02

(51) Int. Cl. H05K 1/11

(52) U.S. Cl. 174/262

(57) ABSTRACT

In a printed circuit board (10), in which at least one signal conductor (13) runs through a dielectric comprising at least one dielectric layer (12, 15), an improved signal integrity in conjunction with simplified producability which is more flexible with regard to the layout is achieved by virtue of the fact that, for electrical radio-frequency screening, the at least one signal conductor (13) is surrounded by a plurality of electrically conductive holes (18), which are spaced apart from one another.

### TECHNICAL FIELD

The present invention is concerned with the field of printed circuit boards for electrical and/or electronic circuits. It relates to a printed circuit board in accordance with the preamble of claim 1 and also to a method for producing such a printed circuit board.

### PRIOR ART

Printed circuit boards (PCBs) have long been an indispensable part of electronic circuitry. They are either used directly for the construction of electronic circuits and carry and connect the individual electronic components of a circuit, or they have the function of a “backplane”, which interconnects a plurality of other, usually insertable, printed circuit boards with electronic circuits on the rear side of a larger unit.

In modern telecommunications and data processing the development tends towards ever higher operating frequencies and data rates. This requires not only ever faster electronic components (transistors, ICs, CPUs etc.), but also corresponding connecting lines between the individual circuit sections of an electronic circuit or of a larger system. At frequencies in the GHz range, in particular above 10 GHz, or data rates of 10 Gbps or more, it is increasingly necessary to use specially designed signal lines in order to ensure a sufficient signal integrity of the transmitted signals. This also applies, in particular, to printed circuit boards in the circuit and backplane region.

Therefore, various efforts have already been made in the past to form screened signal lines or coaxial lines on or within a printed circuit board using techniques of printed circuit board production, which lines prevent crosstalk or EMI even at very high operating frequencies. U.S. Pat. No. 3,613,230 has already described a method enabling the production of miniaturized microcoaxial lines using techniques of printed circuit board production, in the case of which lines conductor tracks which are embedded in a dielectric between two parallel conductor areas are screened by conductively filled trenches which run parallel to and between the conductor tracks and reach from the upper to the lower conductor area.

U.S. Pat. No. 6,000,120 discloses a method enabling the production of comparable microcoaxial lines, which are laterally screened by conductively filled trenches, on the surface of a large-scale integrated printed circuit board by progressively constructing various structured layers by means of photolithographic methods.

Finally, WO-A2-00/14771 or WO-A1-00/16443 describes a method for producing EMI-screened conductor tracks in a printed circuit board in which a conductor track embedded in a dielectric of the printed circuit board between two conductive layers is screened by lateral trenches, which are lined in an electrically conductive manner, with the formation of a coaxial line structure (see FIGS. 9-12 therein and the associated description). In this known method, the trenches in the printed circuit board which are required for the lateral screening are excavated by means of laser or plasma removal of the board material. What is disadvantageous with this type of procedure is that excavating long trenches results in a high outlay in respect of time and costs. Furthermore, considerable restrictions in the flexibility of the printed circuit board layout result from the need to form the trenches in a continuous fashion.

### SUMMARY OF THE INVENTION

Therefore, it is an object of the invention to provide a printed circuit board having integrated screen signal lines which avoids the disadvantages of known printed circuit boards and is distinguished in particular by simplified production and significantly increased flexibility in the layout, and also to specify a method for producing it.

The object is achieved by the totality of the features of claims 1 and 22. The heart of the invention consists in providing, for the lateral screening of the signal line, rather than continuous trenches lined in an electrically conductive manner, rows of holes which are arranged one behind the other and are lined in an electrically conductive manner, the gaps between the individual holes or the distance between the holes depending on the wavelength of the highest frequency to be transmitted. If the distance between the holes in a row is chosen appropriately, the rows of holes have essentially the same screening effect as continuous trenches, but can be produced much more rapidly and more simply. Furthermore, the individual holes provide additional leeway margins in the layout of the printed circuit board.

A first preferred refinement of the printed circuit board according to the invention is characterized in that the electrically conducted holes run perpendicularly between two earth layers, which lie one above the other in the printed circuit board and are isolated by dielectric layers, and are electrically conductively connected to the said earth layers. The earth layers not only ensure an optimum electrical connection of the holes, but can at the same time be part of the screening of the at least one signal conductor. In this case, the inner walls of the electrically conductive holes are covered in particular with an electrically conductive through-plating layer, preferably made of Cu.

In this case, the two earth layers may be arranged within the printed circuit board. However, the two earth layers may also be arranged in regions near the surface of the printed circuit board.

An optimum screening effect is achieved by the holes if the distance between the electrically conductive holes amounts to approximately λ/4 where λ is the wavelength with respect to the maximum signal frequency to be transmitted on the at least one signal conductor.

Likewise, the radio-frequency behaviour of the screened signal line is particularly favourable if the lateral distance between the electrically conductive holes and the at least one signal conductor, measured from the centre of the at least one signal conductor to the axis of the holes, is proportional to the distance between the earth layers, with a proportionality factor lying in the range between ¼ and 5.

The electrically conductive holes may be formed in a conventional manner as holes produced by a mechanical drill. The electrically conductive holes then preferably have an internal diameter of between 0.05 mm and 1 mm.

In this case, the electrically conductive holes are designed either as continuous holes through the printed circuit board or as blind via holes ending in the printed circuit board.

However, the electrically conductive holes may also be designed as holes produced by a laser beam. The electrically conductive holes then preferably have an internal diameter of between 0.02 mm and 0.5 mm. In particular, the electrically conductive holes may be produced in a multi-stage laser method, preferably in accordance with the method disclosed in International Patent Application No. WO-A1-00/41447.

The at least one signal conductor can adopt different configurations relative to the holes. Thus, it is conceivable for the at least one signal conductor to run parallel to the electrically conductive holes. In this case, by way of example, the at least one signal conductor may be designed as a plated-through hole in the printed circuit board.

In another possible configuration, the electrically conductive holes run perpendicularly to the at least one signal conductor, and the electrically conductive holes are in each case arranged laterally with respect to the at least one signal conductor one behind the other in a line which runs parallel to the at least one signal conductor.

In particular, the electrically conductive holes run perpendicularly between two parallel earth layers, which lie one above the other in the printed circuit board and are isolated by dielectric layers, and are electrically conductively connected to the said earth layers, and the at least one signal conductor runs in the centre between the earth layers in a plane parallel to the earth layers.

It goes without saying that it is possible for a plurality of signal conductors to be arranged next to one another in the same plane in this case.

The screening properties are particularly favourable if, in accordance with another refinement of the invention, provision is made of earth traces running parallel laterally with respect to the at least one signal conductor in the plane of the at least one signal conductor, which earth traces are electrically conductively connected to the electrically conductive holes, the lateral earth traces preferably being arranged in such a way that the electrically conductive holes pass through them.

A preferred refinement of the method according to the invention is characterized in that firstly holes are introduced into the printed circuit board and then the inner walls of the holes are lined with an electrically conductive through-plating layer.

In one variant, the holes are introduced mechanically into the printed circuit board. In this case, they may be embodied as blind holes or through the printed circuit board.

However, it is also conceivable for the holes to be embodied as buried holes by multiple pressing of the printed circuit board.

In another variant, the holes are introduced into the printed circuit board by a laser beam in a multi-stage method, preferably in accordance with the method disclosed in International Patent Application No. WO-A1-00/41447.

### BRIEF EXPLANATION OF THE FIGURES

The invention will be explained in more detail below using exemplary embodiments in connection with the drawings, in which

FIG. 1 shows, in a perspective sectional view, a detail from a printed circuit board with an integrated signal conductor which is screened by electrically conductive holes and runs in the board plane, in accordance with a first exemplary embodiment of the invention;

FIG. 2 shows, in a view comparable to FIG. 1, a second preferred exemplary embodiment of the invention with two screened signal conductors running parallel;

FIG. 3 shows a third preferred exemplary embodiment of the invention, in which lateral earth traces (ground traces) are additionally provided for screening in the plane of the signal conductor;

FIG. 4 shows a fourth preferred exemplary embodiment of the invention, analogous to the example of FIG. 3, with lateral earth traces, in which the holes are formed as laser-produced “microvias”;

FIG. 5 shows, in an illustration and arrangement comparable to FIG. 4, a fifth preferred exemplary embodiment of the invention with “microvias” as holes, but without additional earth traces;

FIG. 6 shows a sixth preferred exemplary embodiment of the invention, comparable to FIG. 1, in which the holes are formed as blind holes (“blind vias”);

FIG. 7 shows a seventh preferred exemplary embodiment of the invention, in which the holes are formed as continuous holes and screen a plurality of signal conductors arranged one above the other;

FIG. 8 shows an eighth preferred exemplary embodiment of the invention, in which the holes screen a signal conductor in the form of a plated-through hole;

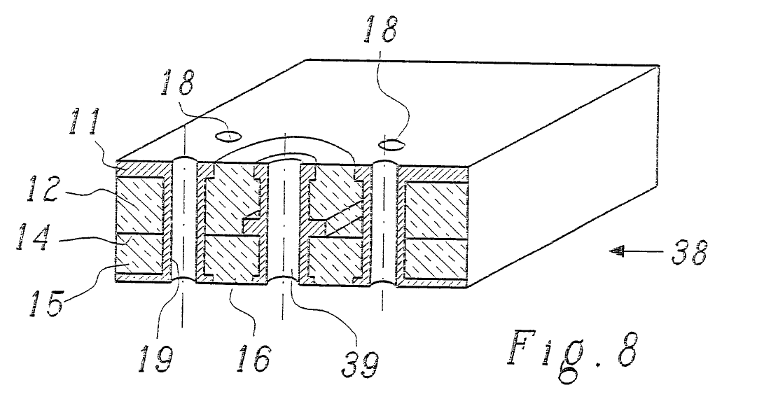

FIG. 9 shows, in a number of sub-figures (FIGS. 9a-c), different steps on the way to producing a printed circuit board in accordance with FIG. 7;

FIG. 10 shows the further processing of a board according to FIG. 9c to form a printed circuit board, in which the holes are formed as blind holes (“blind vias”);

FIG. 11 shows the further processing of a board according to FIG. 9c to form a printed circuit board, in which the holes are formed as buried holes (“buried vias”); and

FIG. 12 shows, in various sub-figures (FIGS. 12a-f), various steps on the way to producing a printed circuit board according to FIG. 4.

### WAYS OF EMBODYING THE INVENTION

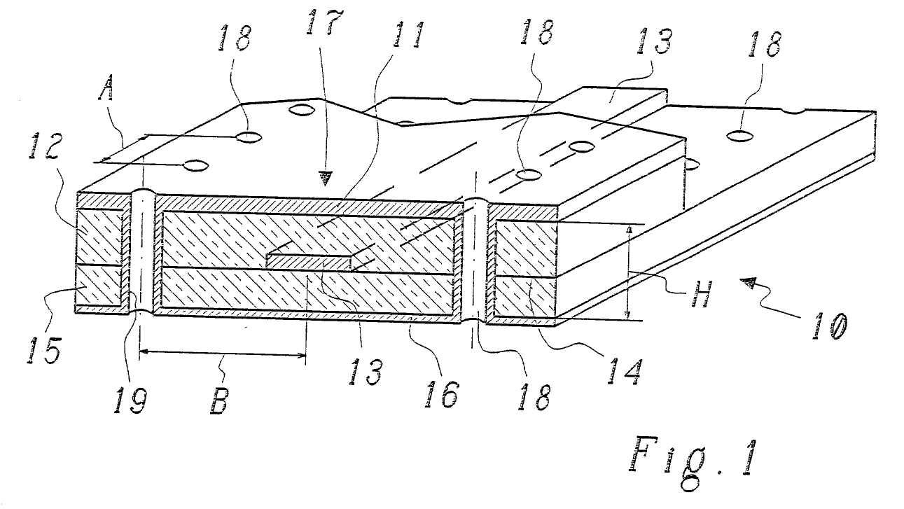

FIG. 1 shows, in a perspective sectional view, a detail from a printed circuit board with an integrated signal conductor which is screened by electrically conductive holes and runs in the board plane, in accordance with a first exemplary embodiment of the invention. The printed circuit board 10 may be a multilayer board having a multiplicity of dielectric and conductive layers, of which FIG. 1 only shows two dielectric layers 12 and 15 directly lying one above the other and also two earth layers (“ground”) 11 and 16, between which the dielectric layers 12 and 15 are arranged. At the layer boundary 14 between the two dielectric layers 12 and 15, parallel to the earth layers 11, 16, a signal conductor 13 is embedded in the dielectric material. The signal conductor 13 is screened towards the top and bottom by the earth layers 11 and 16. In order to be able to better discern the course of the signal conductor 13, the upper earth layer 11 and the upper dielectric layer 12 are omitted in the rear part of the arrangement.

Two rows of holes 18, which are arranged on both sides of the signal conductor 13 in lines running parallel to the signal conductor 13, are provided for the lateral screening of the signal conductor 13. The holes 18 reach through the layer sequence comprising earth layers 11, 16 and dielectric layers 12, 15. On the inner wall, they are provided with an electrically conductive through-plating layer and are thus electrically conductively connected to both earth layers 11 and 16. The through-plating layer 19 can be produced according to the customary through-plating methods in printed circuit board manufacturing and are composed of Cu, for example.

The electrically conductive holes 18, together with the earth layers 11, 16, enclose the signal conductor 13 and form together with it a microcoaxial line 17. In order that the holes 18 exercise a screening function on the signal conductor 13 at predetermined signal frequencies, their arrangement should be chosen in a suitable manner. Thus, the distance A between the uniformly spaced-apart, electrically conductive holes 18 should lie within a suitable range of magnitudes. By way of example, a distance A of the order of magnitude of λ/4, where λ is the wavelength with respect to the maximum signal frequency to be transmitted on the signal conductor 13, has proved expedient. However, other distances A are also conceivable depending on the requirement imposed on the screening properties. Furthermore, the lateral distance B between the electrically conductive holes 18 and the signal conductor 13, measured from the centre of the signal conductor 13 to the axis of the holes 18, should be proportional to the distance H between the earth layers 11, 16, with a proportionality factor lying in the range between ¼ and 5. The orders of magnitude of the distance A which occur in this case can be read from the following table, which presents the associated wavelength λ=c/f with respect to a plurality of frequencies f:

| f[GHz] | 10 | 20 | 30 | 40 |
|---|---|---|---|---|
| λ[mm] | 30 | 15 | 10 | 7.5 |

Thus, if e.g. the signal conductor is to be designed for the maximum frequency of 10 GHz, a (maximum) distance A between the holes 18 of 7.5 mm results—taking the abovementioned λ/4 example.

The holes 18 can be produced mechanically by corresponding drills. This makes it possible to realize internal diameters of the holes 18 in a range from 0.05 mm to 1 mm. However, the holes 18 can also be produced by means of a laser. In this way, it is possible to achieve internal diameters of the holes 18 in the range between 0.02 mm and 0.5 mm.

The dielectric layers 12, 15 may be made, for example, from the expensive material ARLON 25FR, which is suitable for high frequencies, and in each case have a thickness of about 100 μm. However, it is also conceivable for the dielectric layers 11, 15 to be composed of so-called thin glass as has already been proposed by the applicant for the construction of printed circuit boards (in this respect, see the document WO-A1-00/50946). As a result of the screening effect of the holes, however, an optimum connection can also be produced with less expensive dielectric materials. The earth layers 11, 16 are composed of Cu and have thicknesses for example of about 50 μm if they are situated on the surface of the printed circuit board 10 or of about 20 μm if they are situated within the printed circuit board 10.

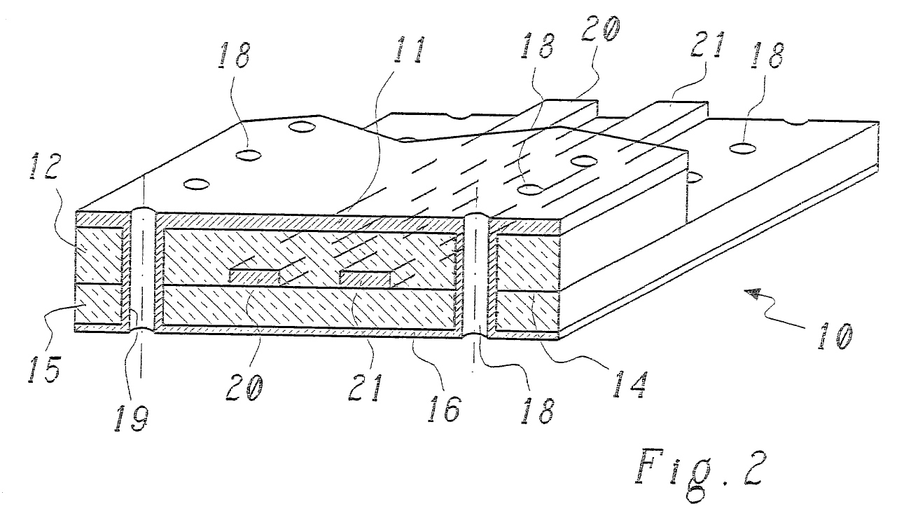

A further exemplary embodiment of a printed circuit board 10 according to the invention is illustrated in FIG. 2, where two differential signal conductors 20, 21, which are jointly utilized for the signal transmission, are situated in the screened “chamber” formed by the rows of holes 18 and by the sections of the earth layers 11, 16 between the rows of holes. In this case, dimensions and production method are essentially the same as in the configuration in accordance with FIG. 1.

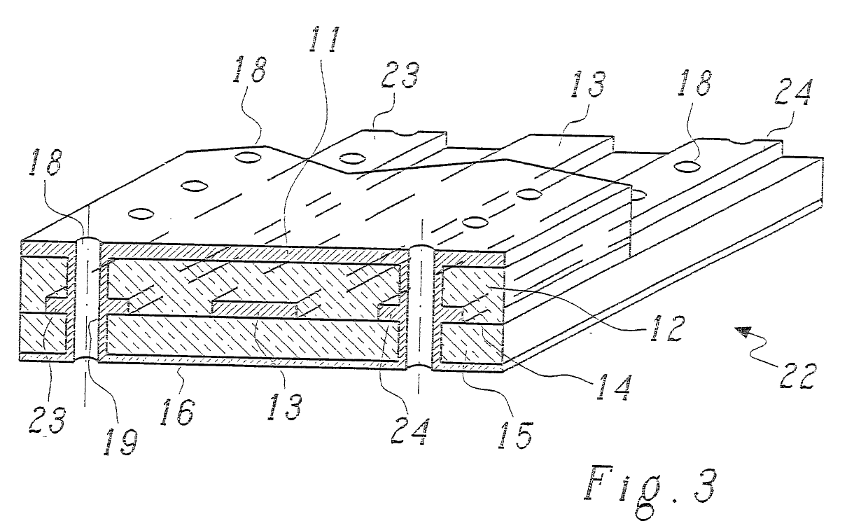

A configuration of the printed circuit board according to the invention which is particularly preferred with regard to the screening properties is represented in FIG. 3. In this printed circuit board 22, earth traces (“ground traces” ) 23, 24 are provided on the plane of the signal conductor 13 parallel to the signal conductor 13 on both sides and they are at the same lateral distance from the (central) signal conductor 13 as the electrically conductive holes 18 and are electrically conductively connected to the latter (and to the earth layers 11, 16). In this case, the earth traces 23, 24 can be introduced into the printed circuit board 22 in a simple manner together with the signal conductor 13 in a common production process.

In the exemplary embodiments shown in FIGS. 1 to 3, that part of the printed circuit board 10 or 22 which is equipped with the signal conductor 13 is firstly completed in the layer sequence. Afterwards, the holes 18 are introduced and, finally, the through-platings (through-plating layer 19) are performed.

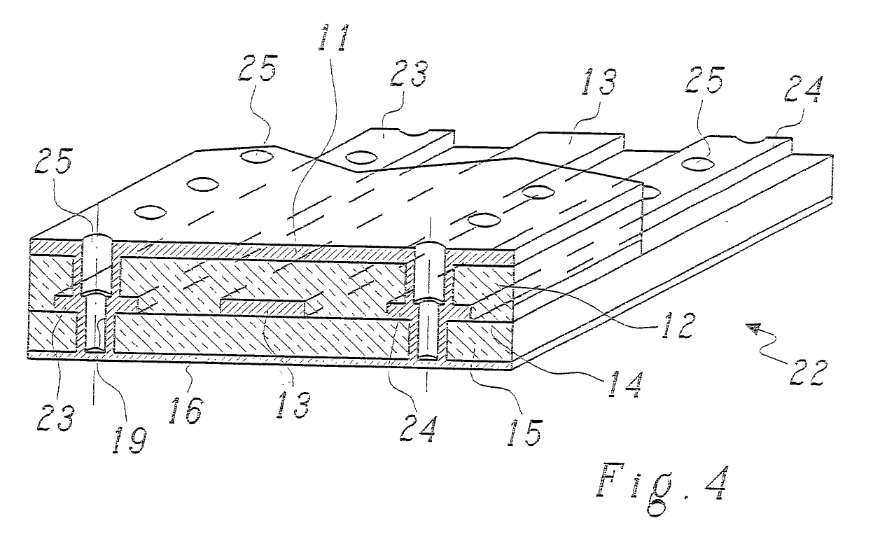

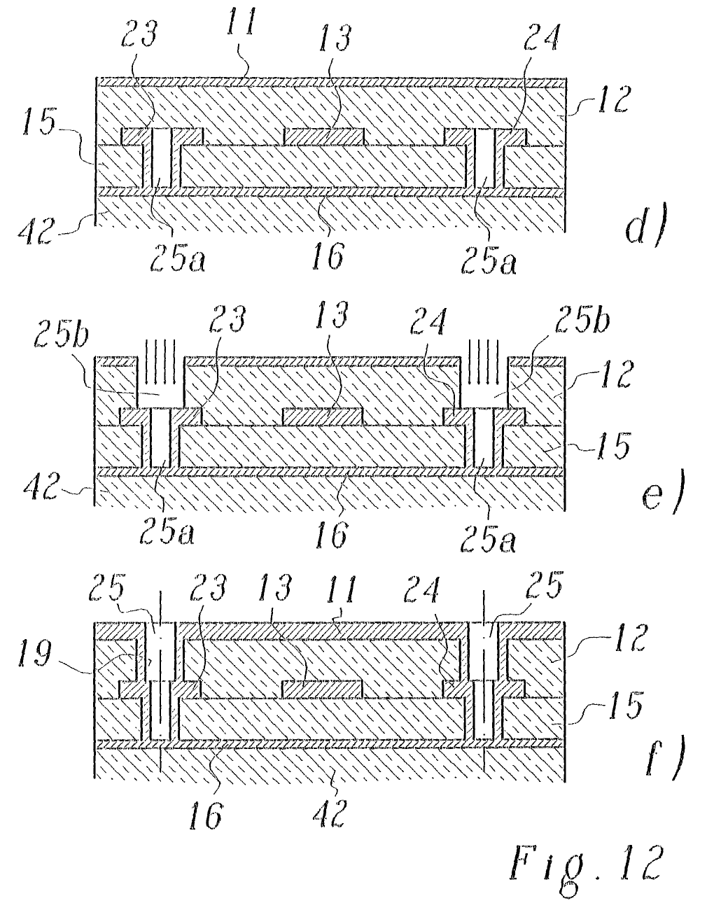

If the microcoaxial lines are provided in the surface region of the printed circuit board, a sequential method working with a laser beam can also be employed, which method has been developed by the applicant and produces plated-through holes referred to as “Inline Vias” (in this respect, see WO-A1-00/41447) . The result of such a sequential production method using a laser beam is illustrated in FIG. 4, in which case—just as in FIG. 3—lateral earth traces 23, 24 are also provided in the screening of the signal conductor 13. The printed circuit board 22 from FIG. 4 with the sequentially produced holes 25 is the result of a method as represented in individual steps in FIG. 12 (sub-FIG. 12 a-f).

The starting point in accordance with FIG. 12a is a layer structure in which, on a first dielectric layer 42, there are arranged a first earth layer 16, a second dielectric layer 15 and structured conductor tracks in the form of a central signal conductor 13 and two earth traces 23, 24.

In the region of the earth traces 23, 24, in accordance with FIG. 12b, firstly two rows of first partial holes 25a are introduced into the printed circuit board by means of a laser beam (indicated by clusters of arrows in FIG. 12b) through the earth traces 23, 24 and second dielectric layer 15 down to the first earth layer 16. Afterwards, by means of a first plating process, the conductor strips 23, 13 and 24 are reinforced and the first partial holes 25a are through-plated (FIG. 12c).

Then, in accordance with FIG. 12d, a further dielectric layer 12 with a second earth layer 11 is applied (laminated) onto the arrangement thus obtained, with the result that the conductor strips 23, 13 and 24 are largely embedded in dielectric material.

Through the second earth layer 11 and the further dielectric layer 12, coaxially with respect to the first partial holes 25a, second partial holes 25b are introduced down to the earth traces 23, 24 (FIG. 12e) . This is likewise done using a laser beam, as is indicated by the clusters of arrows in FIG. 12e. The exact process control during the laser drilling can, incidentally, be gathered from WO-A1-00/41447 mentioned above.

In a final step (FIG. 12f), by means of a second plating process, the second earth layer 11 is then reinforced and the second partial holes 25b are through-plated. The first and second partial holes 25a and 25b then together form the holes 25, which are electrically conductive by means of a through-plating layer 19 on the inner wall and electrically connect the two earth layers 11 and 16 to one another.

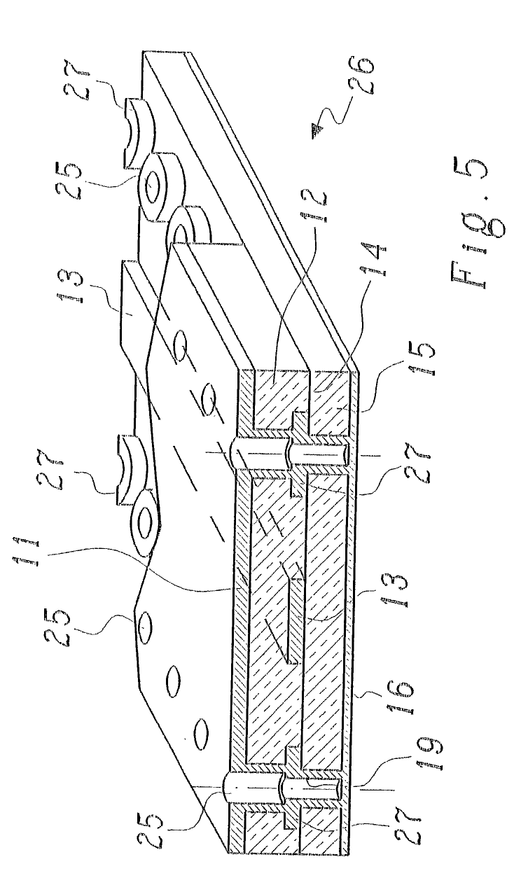

In accordance with FIG. 5, however, the laser-drilled holes (“Inline Vias”) 25 can also be used without earth traces 23, 24, if an intermediate metalization 27 in the form of individual pads is provided on the plane of the signal conductor.

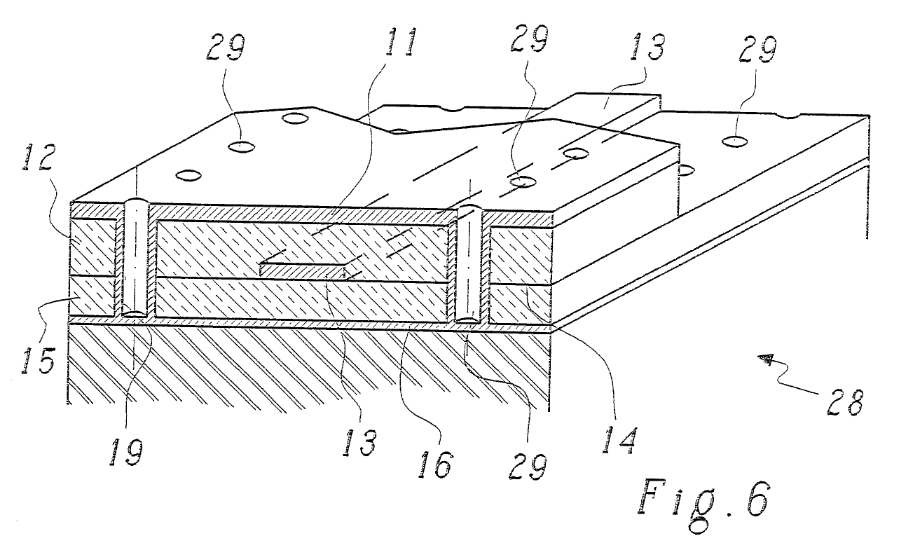

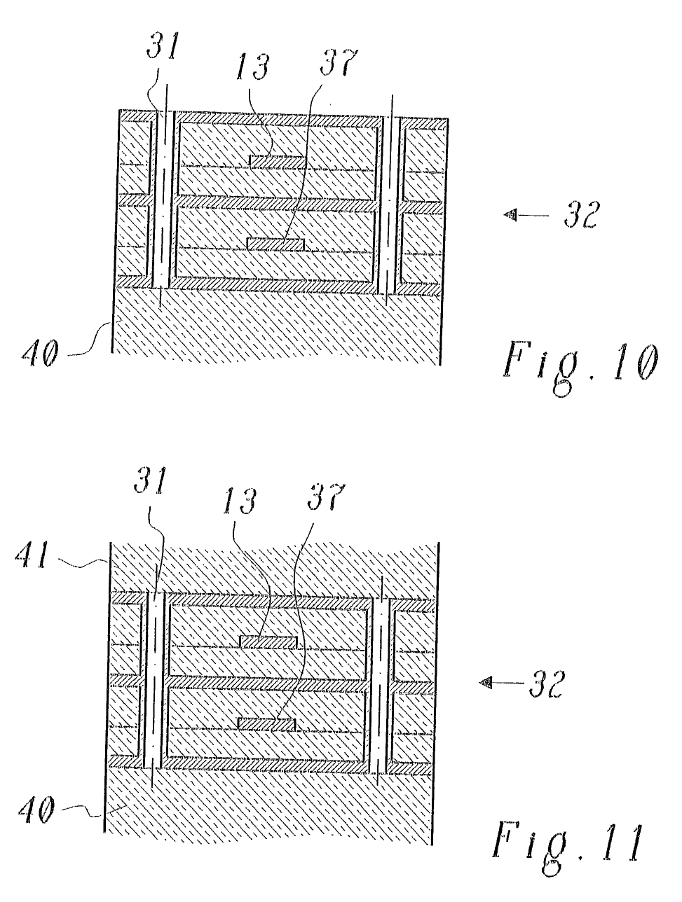

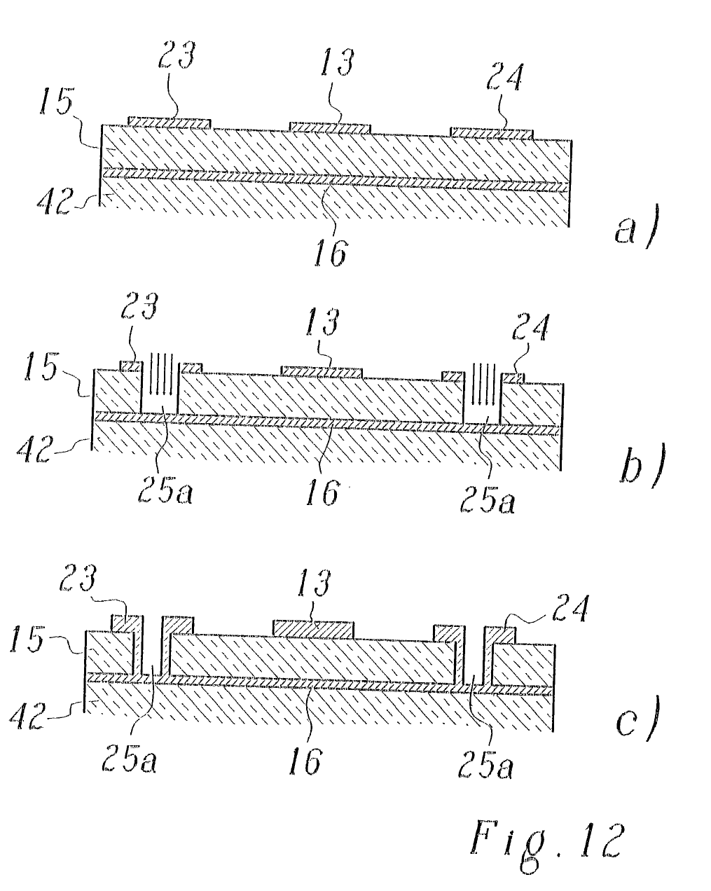

The holes introduced by conventional mechanical means can—if the printed circuit board is produced by multiple pressing—be arranged as buried holes (“buried vias”) within the printed circuit board (see FIG. 11). However, they can also end as blind holes (“blind vias”) within the printed circuit board (in this respect, see FIG. 6 or 10 ). In FIG. 6, in particular, in a configuration comparable to FIG. 1, the holes 29 are embodied as blind holes which end above a next-deeper dielectric layer 30.

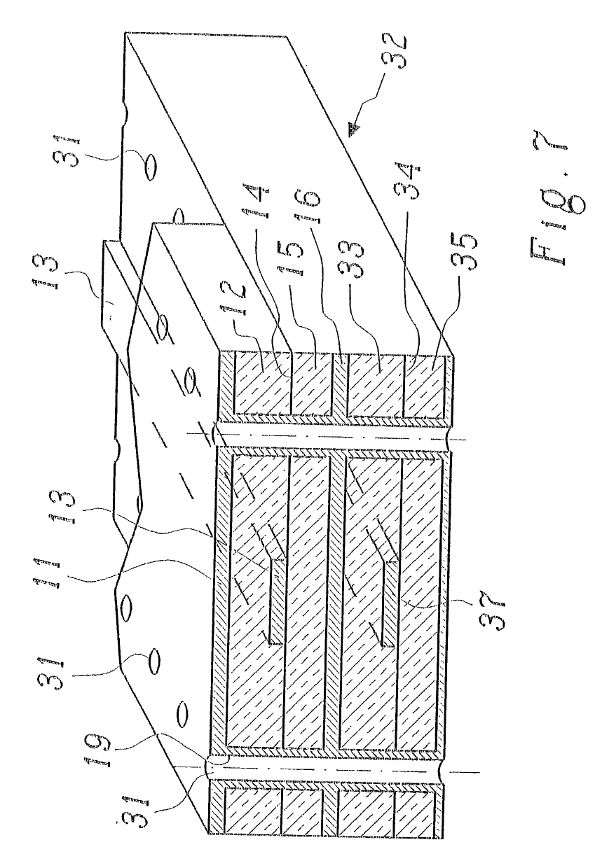

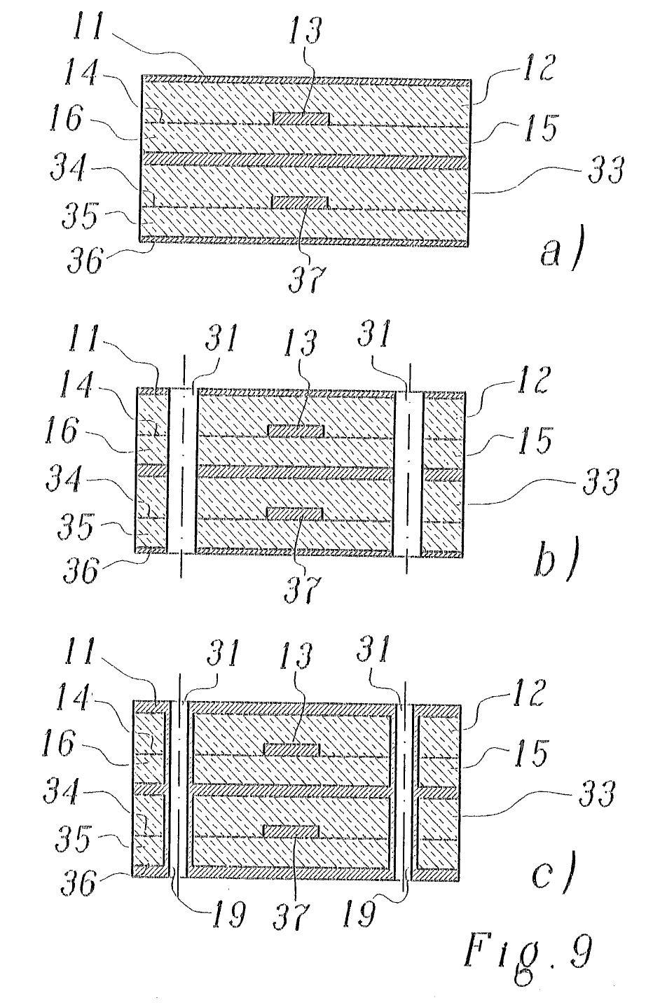

In the case of mechanical holes, a further possibility consists in leading the holes through the entire multilayer printed circuit board and thus producing, for example, a plurality of screened microcoaxial lines one above the other. An example of such a configuration is illustrated in FIG. 7, where the printed circuit board 32 has a layer sequence comprising three earth layers 36, 16 and 11 and twice two dielectric layers 33, 35 and 12, 15, at whose layer boundaries 34 and 14, respectively, a signal conductor 37 and 13, respectively, is in each case arranged. Then—as is illustrated in individual steps in FIGS. 9a-c—two parallel rows of completely continuous holes 31 are introduced (FIG. 9b) into such a layer configuration and subsequently lined (FIG. 9c) with a through-plating layer 19. It goes without saying that additional lateral earth traces (ground traces) in accordance with FIG. 3 can be provided on one or both signal conductor planes in this case as well. If the configuration in accordance with FIG. 7 or 9c is pressed with a further dielectric layer 40 according to FIG. 10, the blind holes already mentioned are produced. If the configuration in accordance with FIG. 7 or 9c is pressed on the top side and underside with two further dielectric layers 40 and 41 according to FIG. 11, the buried holes already mentioned are produced.

However, the screening perpendicular holes may not only be used on both sides of a signal conductor running horizontally but also be arranged around a signal conductor running vertically. Such a configuration of the invention is illustrated in an example in 8. The signal conductor 39 is formed as a vertical plated-through hole in the printed circuit board 38. Around the signal conductor 39, the electrically conductive holes 18 are arranged between the upper and lower earth layer 11 and 16, respectively, and lined with a through-plating layer 19.

Overall, the invention yields a printed circuit board which is distinguished by the following features and advantages:

As transmission rates increase, the signal integrity is accorded ever greater importance. The signal quality can be increased by targeted screening of the conductors (individual conductors, differential conductors edge-coupled or broadside-coupled).

By introducing microvias along the conductors, it is possible to achieve a screening which is equivalent in quality to a continuous screening.

The advantage of holes over continuous screens (e.g. trenches) are the hugely more favourable production costs and the greater flexibility in the design of the layout with the same performance with regard to screening effect.

The conductors are screened by holes or microvias.

The holes can be effected by mechanical holes in the range from 0.05 mm to 1 mm or by laser holes (laser vias) in the range from 0.02 to 0.5 mm. The mechanical holes can be designed as continuous holes or as stepped holes.

The screening by holes enables a cost-optimized screening with the same screening performance as in the case of continuous channels (trenches). The holes can be produced 2-40 times faster than comparable channels. A frequency-and cost-optimized screening can be realized by the choice of distances and diameters of the holes.

Crosstalk between the lines can be prevented by the introduction of an earth trace (“ground trace”). The introduction of the “ground trace” results without an additional production step during the structuring of the inner layers.

Mechanical holes can screen lines on different planes (not only in regions near the surface)

The height H of the chamber screened with holes is arbitrary since the holes can lead through the entire board.

By means of multiple pressing, screens can be realized by “buried vias” (buried holes in the inner part of the board).

By means of multiple pressing, screens can be realized by blind vias (in a part of the printed circuit board).

Holes which run in a manner arranged radially around plated-through holes can also be used to screen plated-through holes in the vertical direction (z-direction).

In contrast to continuous channels, a smaller mechanical stability loss is obtained in the case of holes.

### LIST OF REFERENCE SYMBOLS

10, 22 Printed circuit board (PCB; backplane)

11, 16 Earth layer

12, 15 Dielectric layer

13 Signal conductor

14, 34 Layer boundary

17 Microcoaxial line

18 Hole

19 Through-plating layer

20, 21 Signal conductor

23, 24 Earth trace

25 Hole (“inline via”)

25a, b Partial hole

26, 28, 32, 38 Printed circuit board (PCB; backplane)

27 Intermediate metalization

29 Hole (blind hole)

30 Dielectric layer

31 Hole (through hole)

33, 35 Dielectric layer

36 Earth layer

37, 39 Signal conductor

40, 41, 42 Dielectric layer

A Distance (hole-hole)

B Lateral distance (hole-signal conductor)

H Thickness (dielectric)

1. Printed circuit board (10, 22, 26, 28, 32, 38), in which at least one signal conductor (13; 20, 21; 37, 39) runs through a dielectric comprising at least one dielectric layer (12, 15; 33, 35), characterized in that, for electrical radio-frequency screening, the at least one signal conductor (13; 20 21; 37, 39) is surrounded by a plurality of electrically conductive holes (18, 25, 29, 31) which are spaced apart from one another.

2. Printed circuit board according to claim 1, characterized in that the electrically conducted holes (18, 25, 29, 31) run perpendicularly between two earth layers (11, 16), which lie one above the other in the printed circuit board (10, 22, 26, 28, 32, 38) and are isolated by dielectric layers (12, 15), and are electrically conductively connected to the said earth layers (11, 16).

3. Printed circuit board according to either of claims 1 and 2, characterized in that the inner walls of the electrically conductive holes (18, 25, 29, 31) are covered with an electrically conductive through-plating layer (19), preferably made of Cu.

4. Printed circuit board according to one of claims 1 to 3, characterized in that the two earth layers (11, 16) are arranged within the printed circuit board (10, 22, 26, 28, 32, 38).

5. Printed circuit board according to one of claims 1 to 3, characterized in that the two earth layers (11, 16) are arranged in regions near the surface of the printed circuit board (10, 22, 26, 28, 32, 38).

6. Printed circuit board according to one of claims 1 to 5, characterized in that the distance (A) between the electrically conductive holes (18, 25, 29, 31) amounts to approximately λ/4 where λ is the wavelength with respect to the maximum signal frequency to be transmitted on the at least one signal conductor (13; 20, 21; 37, 39).

7. Printed circuit board according to one of claims 1 to 6, characterized in that the lateral distance (B) between the electrically conductive holes (18, 25, 29, 31) and the at least one signal conductor (13; 20, 21; 37, 39), measured from the centre of the at least one signal conductor (13; 20, 21; 37, 39) to the axis of the holes (18, 25, 29, 31), is proportional to the distance (H) between the earth layers (11, 16), with a proportionality factor lying in the range between 1/4 and 5.

8. Printed circuit board according to one of claims 1 to 7, characterized in that the electrically conductive holes (18, 29, 31) are designed as holes produced by a mechanical drill.

9. Printed circuit board according to claim 8, characterized in that the electrically conductive holes (18, 29, 31) have an internal diameter of between 0.05 mm and 1 mm.

10. Printed circuit board according to either of claims 8 and 9, characterized in that the electrically conductive holes (18, 31) are designed as continuous holes through the printed circuit board (10, 26, 28, 32, 38).

11. Printed circuit board according to either of claims 8 and 9, characterized in that the electrically conductive holes (29) are designed as blind via holes ending in the printed circuit board (28).

12. Printed circuit board according to one of claims 1 to 7, characterized in that the electrically conductive holes (25) are designed as holes produced by a laser beam.

13. Printed circuit board according to claim 12, characterized in that the electrically conductive holes (25) have an internal diameter of between 0.02 mm and 0.5 mm.

14. Printed circuit board according to claim 5, characterized in that the electrically conductive holes (25) are produced in a multi-stage laser method, preferably in accordance with the method disclosed in International Patent Application No. WO-A1-00/41447.

15. Printed circuit board according to one of claims 1 to 14, characterized in that the at least one signal conductor (39) runs parallel to the electrically conductive holes (18).

16. Printed circuit board according to claim 15, characterized in that the at least one signal conductor (39) is designed as a plated-through hole.

17. Printed circuit board according to one of claims 1 to 14, characterized in that the electrically conductive holes (18, 25, 29, 31) run perpendicularly to the at least one signal conductor (13; 20, 21; 37), and in that the electrically conductive holes (18, 25, 29, 31) are in each case arranged laterally with respect to the at least one signal conductor (13; 20, 21; 37) one behind the other in a line which runs parallel to the at least one signal conductor (13; 20, 21; 37).

18. Printed circuit board according to claim 17, characterized in that the electrically conductive holes (18, 25, 29, 31) run perpendicularly between two parallel earth layers (11, 16), which lie one above the other in the printed circuit board (10, 22, 26, 28, 32) and are isolated by dielectric layers (12, 15), and are electrically conductively connected to the said earth layers (11, 16), and in that the at least one signal conductor (13; 20, 21; 37) runs in the centre between the earth layers (11, 16) in a plane parallel to the earth layers (11, 16).

19. Printed circuit board according to claim 18, characterized in that a plurality of signal conductors (20, 21) are arranged next to one another in the same plane.

20. Printed circuit board according to either of claims 18 and 19, characterized in that provision is made of earth traces (23, 24) running parallel laterally with respect to the at least one signal conductor (13; 20, 21; 37) in the plane of the at least one signal conductor (13; 20, 21; 37), which earth traces are electrically conductively connected to the electrically conductive holes (18, 25).

21. Printed circuit board according to claim 20, characterized in that the lateral earth traces (23, 24) are arranged in such a way that the electrically conductive holes (18, 25) pass through them.

22. Method for producing a printed circuit board according to claim 1, characterized in that, in a printed circuit board (10, 22, 26, 28, 32, 38) in which at least one signal conductor (13; 20, 21; 37, 39) runs through a dielectric comprising at least one dielectric layer (12, 15; 33, 35), laterally with respect to the at least one signal conductor (13; 20, 21; 37), a plurality of electrically conductive holes (18, 25, 29, 31) which are spaced apart from one another are introduced into the printed circuit board (10, 22, 26, 28, 32, 38).

23. Method according to claim 1, characterized in that firstly holes are introduced into the printed circuit board (10, 22, 26, 28, 32, 38) and then the inner walls of the holes are lined with an electrically conductive through-plating layer (19).

24. Method according to claim 23, characterized in that the holes are introduced mechanically into the printed circuit board (10, 28, 32, 38).

25. Method according to claim 24, characterized in that the holes (29) are embodied as blind holes.

26. Method according to claim 24, characterized in that the holes (31) are made through the printed circuit board (32).

27. Method according to claim 24, characterized in that the holes (31) are embodied as buried holes by multiple pressing of the printed circuit board (32).

28. Method according to claim 23, characterized in that the holes (25) are introduced into the printed circuit board (22, 26) by a laser beam in a multi-stage method, preferably in accordance with the method disclosed in International Patent Application No. WO-A1-00/41447.
